(19) United States
(12) Patent Application Publication
(10) Pub. No.: US 2025/0390013 A1
(43) Pub. Date: Dec. 25, 2025

(54) DEEP-BLACK BORDERS ON EUV RETICLES WITH BLAZED GRATINGS

(71) Applicant: KLA Corporation, Milpitas, CA (US)

(72) Inventors: Rajeev Rajendran, San Francisco, CA (US); Farid Atry, San Jose, CA (US); Heng Zhang, Shanghai (CN); Mahsa Farsad, Sunnyvale, CA (US); Santosh Kumar Sankar, San Jose, CA (US); Rush Ogden, Milpitas, CA (US); Wenhua Zhu, Milpitas, CA (US); Rui-Fang Shi, Cupertino, CA (US)

(21) Appl. No.: 18/976,897

(22) Filed: Dec. 11, 2024

Related U.S. Application Data
(60) Provisional application No. 63/661,901, filed on Jun. 20, 2024.
(60) Provisional application No. 63/678,970, filed on Aug. 2, 2024.

(51) Int. Cl. G03F 1/24; G03F 7/00

(52) U.S. Cl. CPC G03F 1/24; G03F 7/70033; G03F 7/70666; G03F 7/706847; G03F 7/706851; G03F 7/7085

(57) ABSTRACT

A lithography mask may include a substrate layer. The lithography mask may include a multilayer reflective film disposed on the substrate layer and forming a first pattern, wherein the multilayer reflective film is configured to receive incident light and reflect a portion of the incident light toward an imaging collection pupil. The lithography mask may include a grating forming a second pattern on the substrate layer and configured to receive the incident light and deflect an additional portion of the incident light outside of the imaging collection pupil. The lithography mask may be inspected by an Actinic Patterned Mask Inspection (APMI) system. The second pattern may include a reflective film deposited on the grating.

### CROSS-REFERENCE TO RELATED APPLICATION

The present application claims the benefit under 35 U.S.C. § 119(e) of U.S. Provisional Application Ser. No. 63/661,901, filed Jun. 20, 2024, and U.S. Provisional Application Ser. No. 63/678,970, filed Aug. 2, 2024, both of which are incorporated herein by reference in their entirety.

### TECHNICAL FIELD

The present disclosure generally relates to lithography masks, and in particular to structured targets on the mask that reduce the reflection of light toward an imaging light collection cone.

### BACKGROUND

The use of extreme ultraviolet lithography (EUVL) in the production of semiconductor chips requires care to prevent unintended extreme ultraviolet (EUV) light and out-of-band (OOB) light from impinging on EUV masks and propagating to the imaging system. One effect of this impingement is the overexposure of edges of chip patterns on the printed substrates to undesired EUV and OOB light. To address this issue, low reflective trenches, referred to as “black borders” (BB) are formed around the patterns of semiconductor device features that reduce the reflection of light into the imaging system. However, these trenches are only partially effective in reducing EUV and OOB reflection. Further, these trenches etched into the substrate of the reticle (e.g., invariably an insulator quartz or low thermal expansion material) form a non-conductive zone detrimental to mask inspection of patterns close to these black borders using electron-based inspection platforms.

EUVL systems may also utilize actuated reticle masking units that limit exposure of neighboring fields to EUV light. However, the manufacture and control of actuated reticle masking slits is difficult, with considerable labor and production costs.

Actinic patterned mask inspection systems (APMI) are microscopes that image a certain field of view (FOV) on the EUV reticle to a sensor at EUV wavelengths to look at defects on the EUV masks. Typically, these FOVs are small (e.g., hundreds of microns), but can have strong position-dependent properties within that small FOV. Critical image-forming metrics like illumination pupil, imaging apodization and imaging wavefront error may have variations across the FOV that need to be measured. Measurements that require field selection, and hence field restriction, on the reticle plane for specific diagnostics become of particular interest as system diagnostics on inspection systems. One way to perform field selection would be by using physical slits that restrict the light collection from specific field zones. However, the small size of the FOVs and selected fields may require that the slit sizes will have to be microscopic as well or need access to magnified conjugate planes of the original field plane elsewhere in the system where macroscopic physical slits can be meaningful and realistic. An alternate method, more elegant and simpler, that avoids the need for microscopic physical slits close to the reticle plane or macroscopic physical slits at alternative conjugate planes within the system, would be to engineer the mask itself as a potential slit. However, this method would require patterns on the reticle that offer extremely high contrast in reflection between the zones that need to be probed (e.g., also referred to as gates) and the area around to emulate a binary slit for field selection.

Therefore, there is a need to develop masks and methods to cure the above deficiencies for EUV scanners and EUV inspection systems.

### SUMMARY

A lithography mask is disclosed, in accordance with one or more embodiments of the present disclosure. In one illustrative embodiment, the lithography mask includes: a substrate layer; a multilayer reflective film disposed on the substrate layer and forming a first pattern, wherein the multilayer reflective film is configured to receive incident illumination and reflect or emit a portion of the incident illumination toward an imaging collection pupil. a grating forming a second pattern on the substrate layer and configured to receive the incident illumination and deflect an additional portion of the incident illumination outside of the imaging collection pupil.

A lithography system is disclosed, in accordance with one or more embodiments of the present disclosure. In one illustrative embodiment, the lithography system includes a lithography sub-system including: a set of optic elements; and a lithography mask, including: a substrate layer; a multilayer reflective film disposed on the substrate layer and forming a first pattern, wherein the multilayer reflective film is configured to receive incident illumination and reflect or emit a portion of the incident illumination toward an imaging collection pupil; and a grating forming a second pattern on the substrate layer and configured to receive the incident illumination and deflect or emit an additional portion of the incident illumination outside of the imaging collection pupil.

An inspection system is disclosed, in accordance with one or more embodiments of the present disclosure. In one illustrative embodiment, the inspection system includes an illumination source configured to generate a beam of illumination. In another illustrative embodiment, the inspection system includes a stage configured to secure an EUV lithography mask, wherein the EUV lithography mask includes a substrate layer, and a multilayer reflective film disposed on the substrate layer and forming a first pattern, wherein the multilayer reflective film is configured to receive incident illumination and reflect or emit a portion of the incident illumination toward an imaging collection pupil; and a grating forming a second pattern on the substrate layer and configured to receive the incident illumination and deflect or emit an additional portion of the incident illumination outside of the imaging collection pupil. In another illustrative embodiment, the inspection system includes a set of optical elements and a detector, a detector, wherein the set of optical elements is configured to direct illumination to the lithography mask and direct illumination from the lithography mask to the detector.

A method for attenuating a reflection from pre-engineered zones of an extreme ultraviolet light (EUV) mask is disclosed, in accordance with one or more embodiments of the disclosure. In one illustrative embodiment, the method includes obtaining a lithography mask including: a substrate layer; a multilayer reflective film disposed on the substrate layer and forming a first pattern; and a grating forming a second pattern on the substrate layer and configured to receive an incident illumination and deflect or emit a portion of the incident illumination outside an imaging collection pupil. In another illustrative embodiment, the method includes illuminating the lithography mask with via an illumination source wherein an illumination of the lithography mask causes illumination incident on the multilayer reflective film to be reflected or emitted into an image collection pupil or an aerial image plane of an optical system, wherein the lithography mask causes illumination incident on the grating to deflect or emit outside of the at least one of the image collection pupil or the aerial image plane.

It is to be understood that both the foregoing general description and the following detailed description are exemplary and explanatory only and are not necessarily restrictive of the invention as claimed. The accompanying drawings, which are incorporated in and constitute a part of the specification, illustrative embodiments of the invention, and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1A illustrates a block diagram of a lithography system for patterning semiconductor device features, in accordance with one or more embodiments of the present disclosure.

FIG. 1B illustrates a block diagram of an inspection system for inspecting EUV masks used in the EUV lithography systems, in accordance with one or more embodiments of the present disclosure.

FIG. 2A illustrates a simplified schematic diagram of a lithography sub-system, according to one or more embodiments of the disclosure.

FIG. 2B illustrates a simplified schematic diagram of an actinic patterned mask inspection system, according to one or more embodiments of the disclosure.

FIG. 3 illustrates a cross-sectional side-view of a lithography mask, in accordance with one or more embodiments of the disclosure.

FIG. 4A illustrates a cross-sectional side-view of a lithography mask, in accordance with one or more embodiments of the disclosure.

FIG. 4B illustrates a cross-sectional side-view of a lithography mask, in accordance with one or more embodiments of the disclosure.

FIG. 5 illustrates cross-sectional views of a symmetrical blazed grating and an asymmetrical blazed grating, in accordance with one or more embodiments of the disclosure.

FIGS. 6A-6D illustrate cross-sectional side views of blazed gratings and their abilities to deflect EUV light and OOB light, in accordance with one or more embodiments of the disclosure.

FIGS. 7A-7C illustrate conceptual views of a system illuminating lithography masks configured with different types of black zone surfaces, in accordance with one or more embodiments of the disclosure.

FIG. 8 illustrates a front view of a lithography mask, in accordance with one or more embodiments of the disclosure.

FIG. 9A illustrates a cross-sectional side-view of a lithography mask, in accordance with one or more embodiments of the disclosure.

FIG. 9B illustrates a front view of a lithography mask, in accordance with one or more embodiments of the disclosure.

FIG. 9C illustrates a process flow diagram depicting a method of attenuating a reflection of unintended extreme ultraviolet (EUV) light or out-of-band (OOB) light out of an image collection pupil or an aerial image plane of an EUV lithography system or an EUV inspection subsystem, in accordance with one or more embodiments of the disclosure.

FIG. 10 illustrates an array of graphs depicting simulations of far-field diffraction patterns from a blazed grating at different wavelengths using the finite difference time domain (FDTD) simulation technique, according to one or more embodiments of the disclosure.

FIG. 11A illustrates a graph depicting simulations of effective reflectivity of the light for deep-black borders and normal black borders as seen at the aerial image plane of the system, in accordance with one or more embodiments of the disclosure.

FIG. 11B illustrates a graph depicting simulated ratios between the deep-black border effective reflectivity and normal black border effective reflectivity at a range of wavelengths, in accordance with one or more embodiments of the disclosure.

FIGS. 12A-12B illustrate graphs depicting measured reflectivity comparisons between deep-black borders and normal black borders for EUV light and OOB light, respectively, in accordance with one or more embodiments of the disclosure.

FIG. 13A illustrates reflection states and respective measured aerial images and pupil images for tested normal black border substrates and deep-black border substrates at 198 nm with an imaging NA of 0.8, in accordance with one or more embodiments of the disclosure.

FIG. 13B illustrates reflection states and respective measured aerial images and pupil images for tested normal black border substrates and deep-black border substrates at 198 nm with an imaging NA of 0.4, in accordance with one or more embodiments of the disclosure.

FIG. 14A illustrates illustrative pupil images and measured aerial images of light reflecting from a respective normal black border substrate and a deep-black border substrate at 198 nm with an imaging NA of 0.8, in accordance with one or more embodiments of the disclosure.

FIG. 14B illustrates illustrative pupil images and measured aerial images of light reflecting from a respective normal black border substrate and a deep-black border substrate at 198 nm with an imaging NA of 0.4 (e.g., medium NA) in accordance with one or more embodiments of the disclosure.

FIG. 14C illustrates illustrative pupil images and extrapolated aerial images for light reflecting from a respective normal black border substrate and a deep-black border substrate at 198 nm with an imaging NA of 0.2 in accordance with one or more embodiments of the disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments are directed to the production of lithography masks for reducing the amount of impinging illumination, particularly extreme ultraviolet and out-of-band light or emitted (e.g., backscattered or secondary emission) electron beams, from inappropriately propagating toward an image collection cone on both lithography systems and inspection systems, such as Actinic Patterned Mask Inspection (APMI) systems or e-beam based inspection systems. The lithography masks utilize gratings in sections where low reflection of light into the light collection pupil is required, such as in black border areas surrounding a pattern of semiconductor features (e.g., circuit elements). The gratings may also be used to create binary field gates that restrict illumination within specific regions of interest within the imaged field (referred to as light gates, illumination gates, or gates), reducing the effect of extraneous illumination into regions outside the region of interest, and reducing the need for reticle masking blades and/or other light-blocking devices.

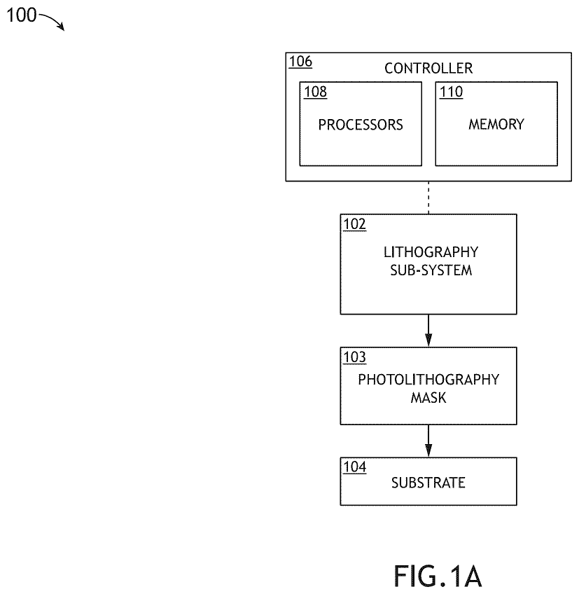

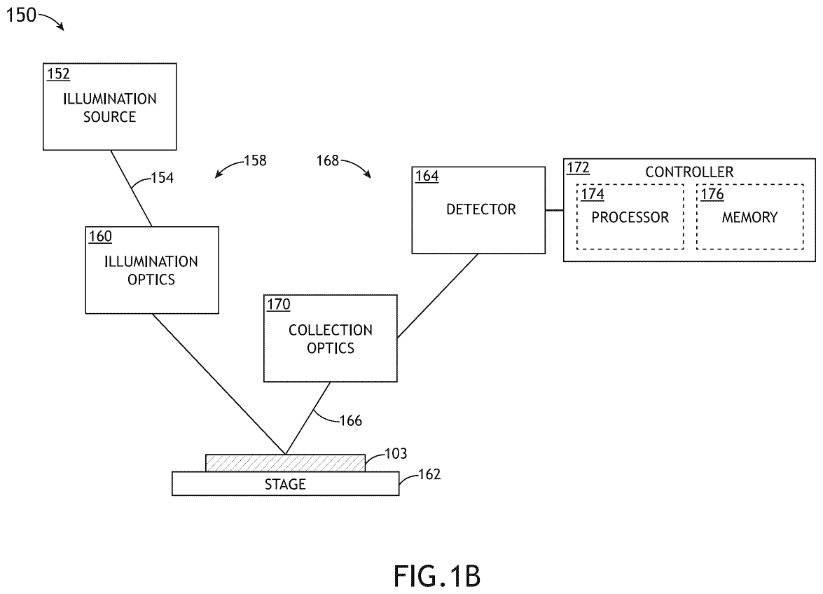

Referring now to FIGS. 1A through 14, systems and methods for reducing illumination from entering into a collection pupil in lithography systems and inspection systems are illustrated in greater detail, in accordance with one or more embodiments of the present disclosure.

FIG. 1A illustrates a block diagram of a lithography system 100 for patterning semiconductor device features, in accordance with one or more embodiments of the present disclosure. The lithography system may include any type of lithography system including reflection-based lithography systems. For example, the lithography system may be configured as an extreme ultraviolet (EUV) light lithography system.

In embodiments, the lithography system 100 includes a lithography sub-system 102 for patterning semiconductor device features from a lithography mask 103 onto a substrate 104 (e.g., a wafer). For example, the lithography sub-system 102 may be configured to generate and/or receive EUV light and transfer a pattern from the lithography mask 103 onto substrate 104 via the EUV light. The lithography sub-system 102 may include any EUV source known in the art capable of generating a beam of EUV light. In embodiments, the system includes one or more controllers 106 configured to control one or more processes of the lithography system (e.g., propagation and/or control of the EUV light, and control and/or movement of lithography system components). The controller 106 may include one or more processors 108 configured to execute program instructions maintained on a memory 110. In embodiments, the lithography system 100 includes an electron beam (e-beam) lithography system.

FIG. 1B is a conceptual view of an inspection system 150, in accordance with one or more embodiments of the present disclosure.

In embodiments, the inspection system 150 includes an illumination source 152 to generate an illumination beam 154. The illumination beam 154 may include one or more selected wavelengths of light including, but not limited to, ultraviolet (UV), extreme ultraviolet (EUV), deep ultraviolet (DUV), or vacuum ultraviolet (VUV) radiation. For example, at least a portion of a spectrum of the illumination beam 154 may include wavelengths below approximately 120 nanometers. By way of another example, the illumination beam 154 includes light of 13.5 nm, 7 nm, or the like. In embodiments, the inspection system 150 includes an electron beam (e-beam) inspection system.

The illumination source 152 may be any type of illumination source known in the art suitable for generating an optical illumination beam 154. In embodiments, the illumination source 152 includes a broadband plasma (BBP) illumination source that encompasses the emission in actinic wavelength. In embodiments, the illumination source 152 may include one or more lasers capable of emitting radiation at one or more selected wavelengths. In embodiments, the illumination source includes an electron beam sources such as an electron gun.

In embodiments, the illumination source 152 directs the illumination beam 154 to a lithography mask 103 via an illumination pathway 168. The illumination pathway 168 may include one or more illumination optics 160 suitable for directing, focusing, and/or shaping the illumination beam 154 on the lithography mask 103. For example, the illumination optics 160 may include one or more lenses or mirrors, one or more focusing elements, or the like. Further, the illumination optics 160 may include any combination of reflective, transmissive, or absorbing optical elements known in the art suitable for directing and/or focusing the illumination beam 154.

In another embodiment, the lithography mask 103 is disposed on a sample stage 162. The sample stage 162 configured to secure the lithography mask 103. The sample stage 162 may include any device suitable for positioning and/or scanning the lithography mask 103 within the inspection system 100. For example, the sample stage 162 may include any combination of linear translation stages, rotational stages, tip/tilt stages, or the like.

In another embodiment, the inspection system 150 includes a detector 164 configured to capture illumination emanating from the lithography mask 103 (e.g., collected light 166 or emitted electrons) through a collection pathway 168. The collection pathway 168 may include, but is not limited to, one or more collection optics 170 for collecting radiation from the lithography mask 103. For example, a detector 164 may receive collected illumination 116 reflected from the lithography mask 103 via the collection optics 170. By way of another example, a detector 164 may receive collected light 166 reflected by the lithography mask 103. The collection optics 170 may include any combination of reflective, transmissive, or absorbing optical elements known in the art suitable for directing and/or focusing the collected light 166. The illumination source 152, the illumination optics 160 and/or the collection optics 170 may be part of an imaging sub-system.

The detector 164 may include any type of detector known in the art suitable for measuring collected illumination, such as EUV light 166 or electron beams received from the lithography mask 103. For example, a detector 164 may include, but is not limited to, a CCD detector, a TDI detector, a photomultiplier tube (PMT), an avalanche photodiode (APD), an electron detector, or the like.

In embodiments, the inspection system 100 includes a controller 172. In embodiments, the controller 172 includes one or more processors 174 configured to execute program instructions maintained on a memory medium 176 (e.g., memory). In this regard, the one or more processors 174 of controller 172 may execute any of the various process steps described throughout the present disclosure.

The controller 172 may be communicatively coupled with any component of the inspection system 150 or any additional components outside of the inspection system 150. In one embodiment, the controller 172 may be configured to receive data from a component such as, but not limited to, the detector 164. For example, the controller 172 may receive any combination of raw data, processed data (e.g., inspection results), and/or partially processed data. In another embodiment, the controller 172 may perform processing steps based on the received data. For example, the controller 172 may perform defect inspection steps such as, but not limited to, defect identification, classification, or sorting.

In another embodiment, the controller 172 may control and/or direct (e.g., via control signals) any component of the inspection system 150. For example, any combination of elements of the illumination pathway 168 and/or the collection pathway 168 may be adjustable. In this regard, the controller 172 may modify any combination of illumination conditions or imaging conditions such as, but not limited to, the illumination or imaging pupil distributions.

The inspection system 150 may be configured as any type of inspection known in the art. Further, the inspection system 150 may be, but is not required to be, an EUV inspection system 150 suitable for interrogating a lithography mask 103 with EUV light. EUV-based mask blank inspection is described generally in U.S. Pat. No. 8,711,346 to Stokowski, issued on Apr. 29, 2014, and U.S. Pat. No. 8,785,082 to Xiong et al., issued on Jul. 22, 2014, both of which are incorporated herein by reference in the entirety. In another embodiment, the inspection system 150 is configured as a wafer inspection system or a reticle inspection system. EUV Imaging is described generally in U.S. Pat. No. 8,842,272 to Wack, issued on Sep. 23, 2014, which is incorporated herein by reference in the entirety.

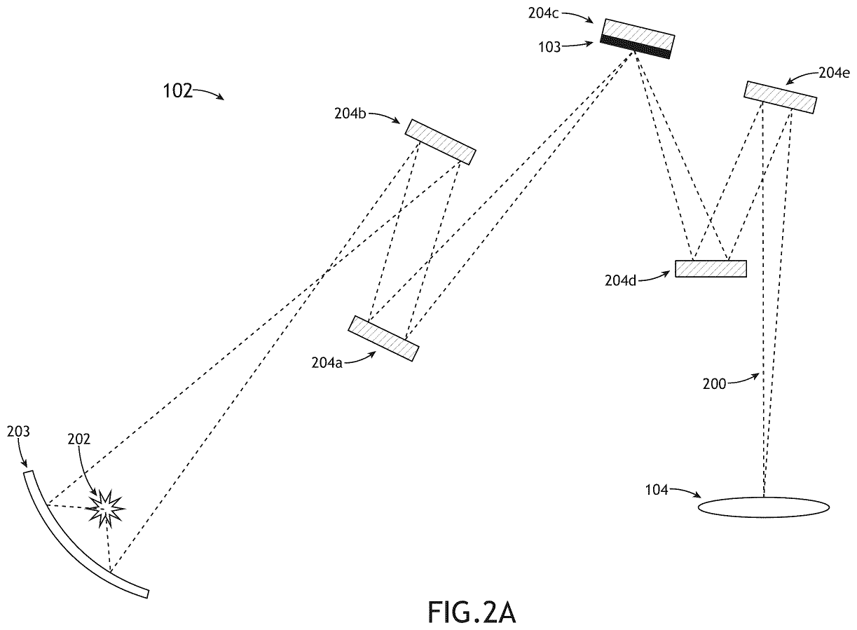

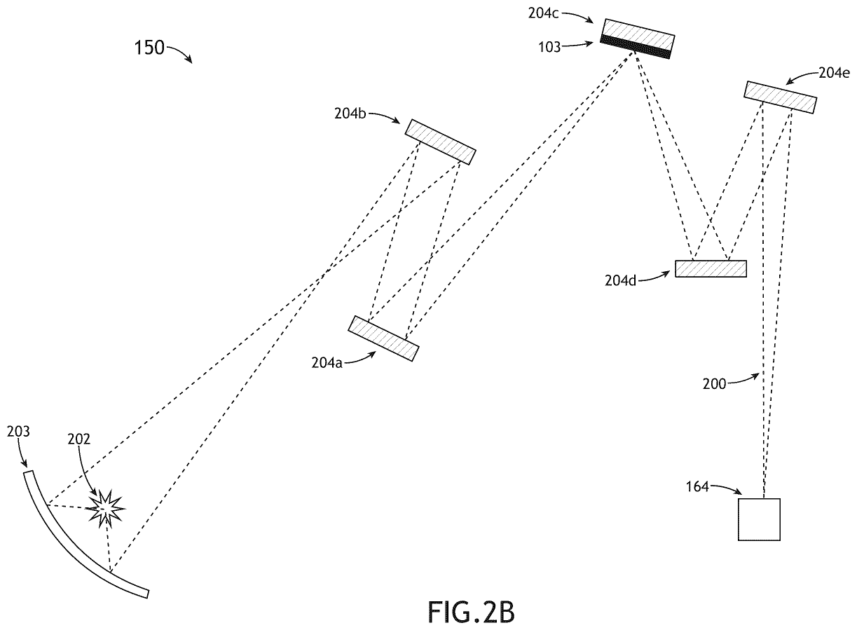

FIG. 2A illustrates a simplified schematic diagram of the lithography sub-system 102, according to one or more embodiments of the disclosure. The lithography sub-system 102 exposes a photoresist-coated substrate 104 to EUV light 200. The EUV light 200 originates from a light source 202. The EUV light 200 is then collected by a collection mirror 203 transmitted to the photoresist-coated substrate 104 via a set of optic elements 204a-e. For example, the lithography sub-system 102 may include one or more illumination optic elements 204a-b to illuminate a patterning optic element 204c, that incorporates a lithography mask 103 (e.g., a reticle). EUV light 200 reflected from the patterning optic includes a patterned beam, which is projected onto the substrate 104 via one or more reduction projection optic elements 204d-e. The lithography sub-system 102 may include one or more components and/or systems for controlling the set of optical elements 204a-e, the EUV light source 202, and the patterning of the substrate 104 including, but not limited to, steppers, scanners, write systems and mechanical assemblies for actuating one or more optical elements of the set of optical elements 204a-e.

FIG. 2B illustrates a simplified schematic diagram of the inspection system 150, according to one or more embodiments of the disclosure. The inspection system 150 exposes the lithography mask 103 to light, such as EUV light 200. The inspection system 150 may include componentry similar to the lithography system 100. For example, the inspection system 150 may include a light source 202, collection mirrors 203 and optical elements 204a-e. The EUV light 200 illuminates the lithography mask 103 via the optical elements 204a-d causing light reflected by the lithography mask 103 to be directed to the detector 164. The inspection system 150 may include any type or number of collection mirrors 203 and other optical elements. Further, the inspection system 150 may include any arrangement of collection mirrors 203 and other optical elements 204. Therefore, the above description should not be considered a limitation of the inspection system 150, but rather an illustration.

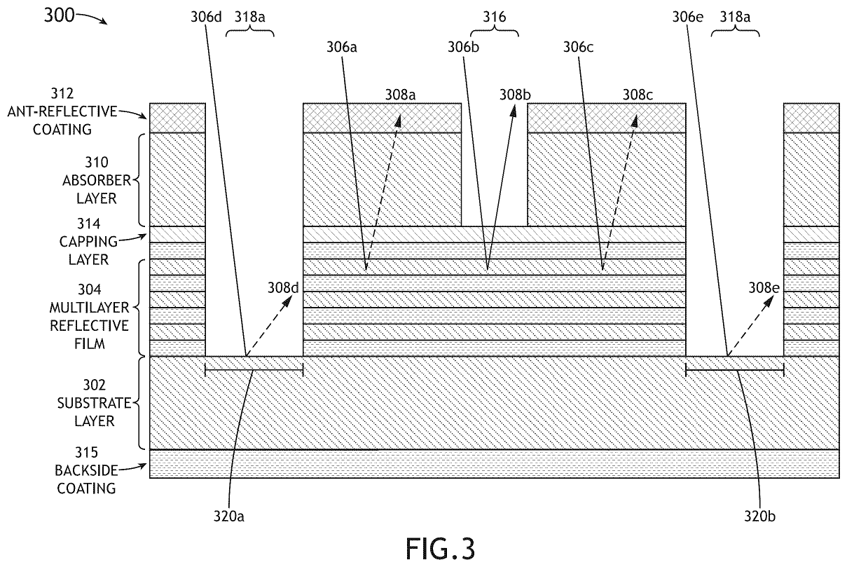

FIG. 3 illustrates a cross-sectional side-view of an EUV lithography mask 300, in accordance with one or more embodiments of the disclosure. The lithography mask 300 may be utilized in semiconductor fabrication systems, such as an EUVL system. The lithography mask 300 may include a substrate layer 302. The substrate layer 302 may include low thermal expansion material (LTEM). The mask 300 may further include a multilayer reflective film disposed on the substrate layer 302 and configured to receive incident illumination 306a-c (e.g., FIG. 3; solid line) and reflect a portion of the incident or emitted illumination 308a-c (e.g., FIG. 3; dotted line). The multilayer reflective film may include several layers of reflective material including, but not limited to, alternating layers of molybdenum material and silicon material. The lithography mask 300 may further include an absorber layer 310 that absorbs incident illumination 306 and/or reflective illumination 308, preventing the majority of the reflective illumination from exiting the lithography mask 300. The absorber layer may include any illumination-absorbing material including, but not limited to, tantalum. The lithography mask 300 may further include an anti-reflective coating 312 that further reduces reflective light of certain non EUV wavelengths from exiting the lithography mask 300. The lithography mask 300 may further include a capping layer 314 that protects the multilayer reflective film from degradation processes and a backside coating at the base of the substrate layer 302.

In embodiments, the lithography mask 300 includes one or more etched areas 316 where the absorbing layer 310 and/or anti-reflective coating 312 has been removed. Incident illumination 306b entering the etched area 316 is reflected off of the multilayer reflective film 304 adjacent to the one or more etched areas, where the reflected light 308b can exit the lithography mask 300 and transmit toward the substrate 104 of the lithography system 100 or the detector 164 of the inspection system 150. The pattern of reflected or emitted illumination 308 from one or more etched areas 316 results in the pattern of semiconductor device features formed on the substrate 104 or magnified image of the reticle on the detector 164.

In embodiments, the lithography mask 300 includes one or more dark zones 318a-b. Dark zones 318a-b are regions of the lithography mask that are substantially attenuated relative to patterned areas, such as the patterned areas formed selective reflection or emission of incident illumination 306 by the multilayer reflective film 304 and the absorber layer 310. Traditionally, the dark zones 318 may include areas of the substrate 104 that do not include multilayer reflective film 304 or absorber layers 310. Incident illumination 306d-e entering the dark zones 318, such as EUV light and OOB light, are reflected poorly. Within an EUV scanner, the substrate projections of the dark zones 318 may enable tight critical dimension (CD) control at the edges of the imaging fields that experience higher dose levels of illumination from multiple exposures than compared to the inner core regions of the imaging fields. Fabrication protocols often require high attenuation of EUV and OOB light at dark zones 318 (e.g., such as black borders surrounding the imaging fields), with reflection rates of EUV and OBB light less than 0.5% and 10.0%, respectively. Traditional black borders that rely on non-structured glass substrate for reducing intrinsic reflectivity are referred to as normal black borders (NBB). Black borders that rely on textured areas for reducing reflection are referred to as hybrid black borders (HBB). Black borders produced by gratings as described herein are referred to as deep black borders (DBB). Dark zones 318 may refer to black borders and/or to other areas within the lithography mask 103 where EUV and/or OOB reflection (e.g., unintended reflection) into the image collecting pupil and/or aerial image plane is to be attenuated.

We note that dark zones 318a, 318b may further include regions 320a, 320b where electrical continuity is disrupted, due at least in part to the loss of the multilayer reflective film 304. The disruption of electrical continuity in these regions 320a, 320b may prevent effective inspection of the lithography mask 300 by electron-beam (e-beam) inspection methods, as detailed below.

Within an inspection system, the dark zones on a diagnostic reticle provide non-physical reticle-based slits for field selection that have high reflectivity contrast between the structured substrate and the multi-layer areas. This allows measuring far field pupil properties that are field selective critical in mask modelling in die-to-database inspections.

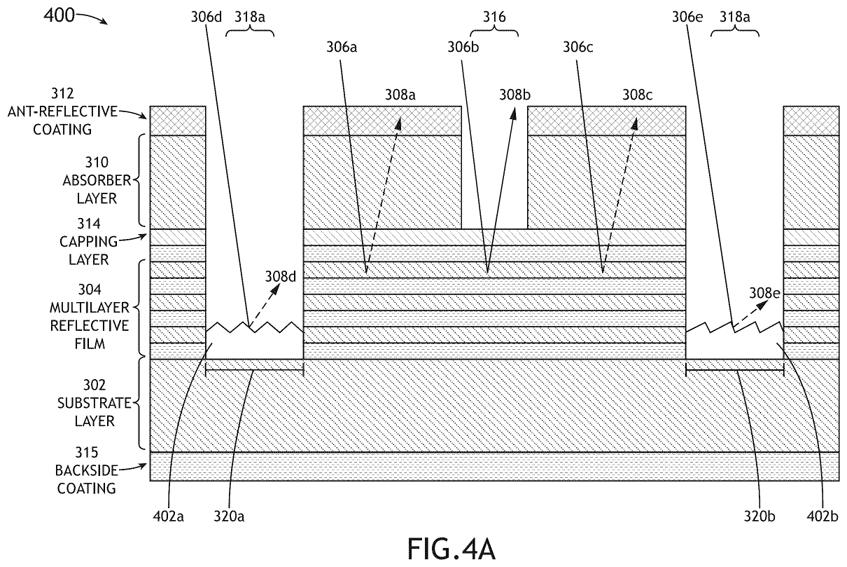

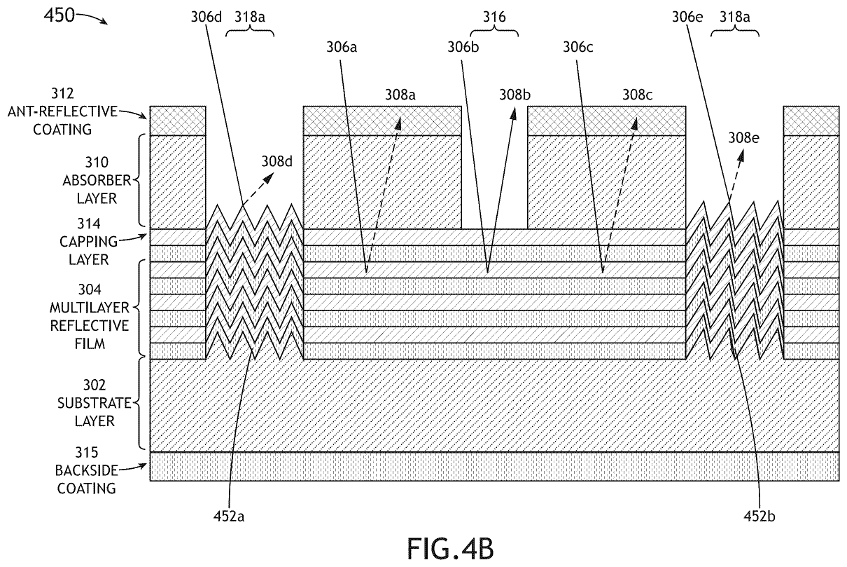

FIG. 4A illustrates a cross-sectional side-view of a lithography mask 400, in accordance with one or more embodiments of the disclosure. The lithography mask 400 may include one or more components or layers than the lithography mask 300.

In embodiments, the lithography mask 400 includes one or more gratings 402a-b, microscopic, structured targets configured to receive the incident illumination 306d-e and reflect or emit incident illumination 308d-e away from an imaging collection pupil (e.g., an imaging collection pupil configured to receive patterned illumination and focus the patterned illumination onto the substrate 104). The one or more gratings 402a-b reduce reflected or emitted light illumination from the dark zones 318 to levels lower than the dark zones in lithography masks 300 that do not include the one or more gratings 402a-b. For example, lithography masks 400 that include one or more gratings 402a-b may reduce by more than an order of magnitude the reflected or emitted illumination 308 out of the dark zones 318 than a lithography mask 300 that does not include the one or more gratings 402a-b. For instance, a lithography mask 400 that includes one or more gratings 402a-b may achieve a reduction in reflected or emitted illumination levels at the aerial image plane, both in the EUV and OOB bands, with effective reflectivity of <0.00025% and <0.3%, respectively. The gratings 402a-b may be composed of substrate material (e.g., from the substrate layer 302) or may be formed from other material that has been applied to the surface of the substrate layer 302. Areas of lithography masks 400 that include gratings 402 may also be referred to as High Opacity Broad Band Imaging Targets (HOBBITS) In embodiments, the one or more gratings 402a-b may be configured as blazed gratings. Blazed gratings, also referred to as echlette gratings, are a type of diffraction grating configured with a sawtooth profile, which may be optimized to achieve a maximal or near maximal grating efficiency in a given diffraction order. In embodiments, the one or more gratings 402a-b may be configured as a symmetrical blazed grating 402a or an asymmetrical blazed grating. In this manner, the lithography mask 400 exploits a strong and characteristic non-specular deflection response of blazed gratings 402a-b (e.g., uncoated/coated asymmetric blazed gratings 402b or coated symmetric blazed gratings 402a) outside the system collection cone instead of the standard specular response from a non-patterned glass surface. The use of blazed gratings 402a-b is an improvement upon lithography masks 300 that do not include blazed gratings 402a-b, which often relied on specular illumination suppression either by choice of the anti-reflective material or engineering its surface for anti-reflection by graded refractive indexing. In the lithography mask 400 of the current disclosure, instead of targeting low illumination levels exiting right at the reticle/mask, illumination suppression is engineered differently by combining illumination deflection offered by the blazed grating 402a-b and its expulsion from the system collection cone. Unlike traditional illumination attenuation, such as the illumination attenuation provided by the attenuation mask 300 without blazed gratings 402, the reflected or emitted illumination levels exiting the reticle/mask can be high, however, the average momentum of that reflected or emitted illumination is directed away from the imaging path, paving a way for dark aerial images and consequently deep-black borders.

FIG. 4B illustrates a cross-sectional side-view of a lithography mask 450, in accordance with one or more embodiments of the disclosure. The lithography mask 400 may include one or more components or layers than the lithography mask 300, 400.

In embodiments, the lithography mask 450 includes grating structures 452a, 452b that include the layers of the multilayer reflective film 304 and/or capping layer 314 that are layered over the gratings 402a, 402b. The grating structures 452a, 542b, 402a maintain the electrical continuity across the lithography mask 450. This allows the lithography mask 450 to have an effective deep black border for both EUV inspection systems and e-beam systems. For example, while black bordering on the substrate layer 302 for NBB, HBB or DBB are typically produced by either etching away the mask stack to expose the underlying substrate that has low EUV reflectivity (e.g., NBB), or by structuring them nanoscopically (e.g., HBB) or microscopically (e.g., DBB), these techniques do not resolve the electron charging problem prevalent in e-beam based mask inspection systems due to the insulator nature of the substrate. Reliable mask inspection by e-beam systems can occur if the black borders are conductive. However, conducting layers typically have high reflectivity and therefore do not work well for black border design. By generating a DBB as the substrate base of the lithography mask 450 and coating a stack of multilayer film on top of the blazed gratings 402a, 402b of the DBB, and by ensuring continuity across the lithography mask 450, the lithography mask 450 preserves the dark nature of black borders guarantees electrical conductivity across the lithography mask 450, enabling reliable e-beam inspection near the black borders.

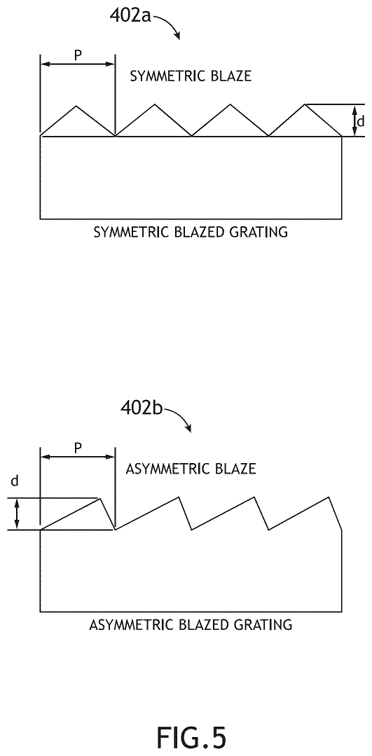

FIG. 5 illustrates cross-sectional views of the symmetrical blazed grating 402a (e.g., containing symmetric blazed grating elements) and the asymmetrical blazed grating 402b (e.g., containing asymmetric blazed grating elements), in accordance with one or more embodiments of the disclosure. The blazed gratings 402a-b are constructed with line spacings ‘p’ and a grating depth “d”. The line spacings and grating depth shown in FIG. 5 shown elsewhere may not be to scale, and may include different characteristics such as incidence angle, diffraction angle, and diffraction order. The blazed grating 402a-b may also be configured as a 1D grating or a 2D grating. Therefore, the above description should not be considered a limitation of the blazed grating 402a-b and lithography mask, but rather an illustration.

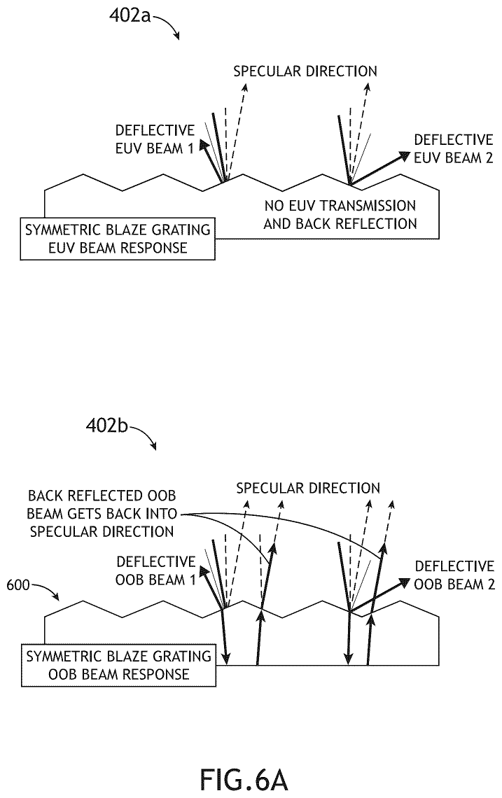

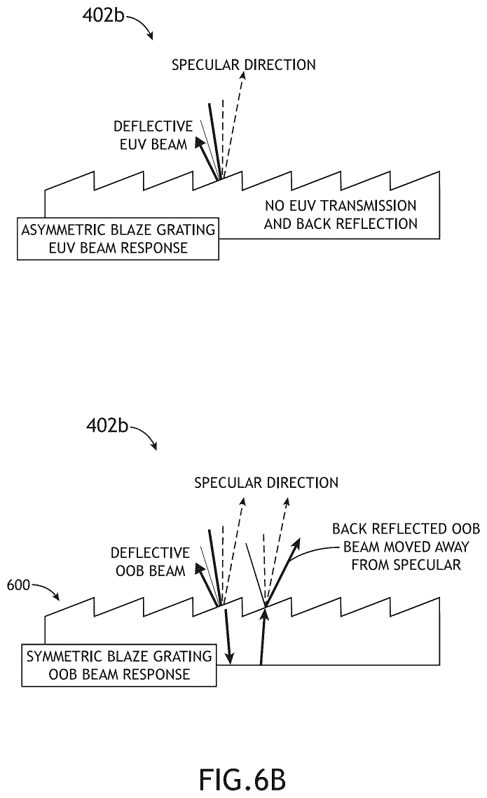

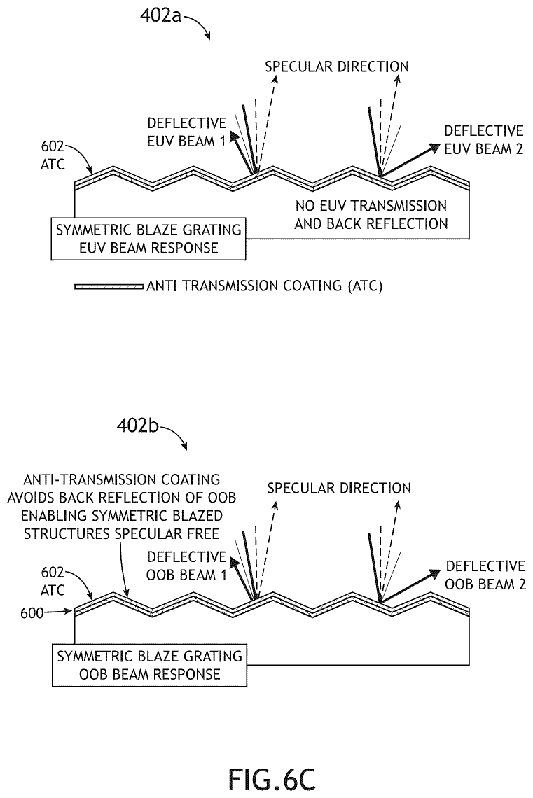

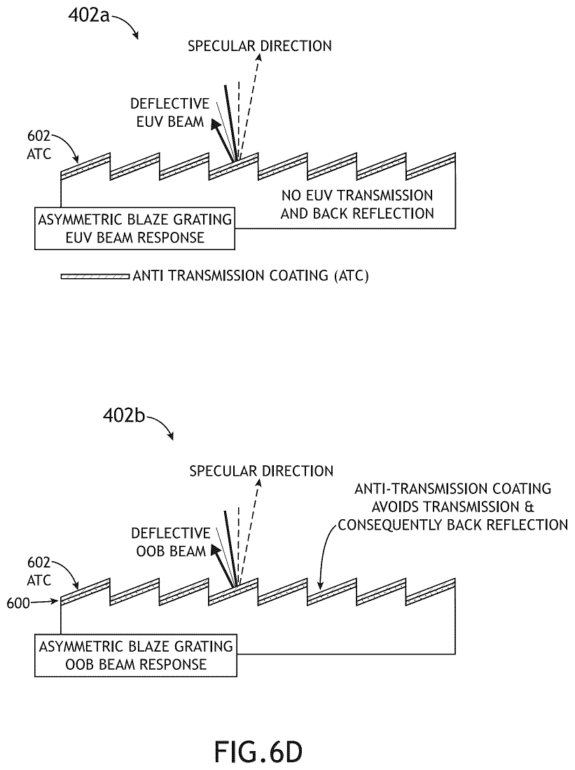

FIGS. 6A-6D illustrate cross-sectional side views of the blazed gratings 402 and their abilities to deflect EUV and OOB light, in accordance with one or more embodiments of the disclosure. As shown in FIG. 6A, reflections of incident light upon the symmetrical blazed gratings 402a for EUV light (FIG. 6A; left) or OOB light (FIG. 6A; right) are shown. For symmetrical blazed gratings receiving EUV light, the EUV beam (e.g., solid-line) is reflected in a different direction from the specular direction (e.g., the specular direction referring to the direction of reflection had there been no blazed grating 402a). In contrast, while some OOB light is similarly reflected as the EUV light, a portion of the OOB light transmits through the top surface 600 of the blazed grading 402a, and reflecting off of a lower surface, the reflection off of the lower surface reflecting in a manner similar to specular reflection, and possibly toward the substrate 104.

As shown in FIG. 6B, reflections of incident light upon the asymmetrical blazed gratings 402b for EUV light (FIG. 6B; left) or OOB light (FIG. 6B; right) are shown. For asymmetrical blazed gratings receiving EUV light, the EUV beam (e.g., solid-line) is reflected in a different direction from the specular direction, similar to shown in FIG. 6A. OOB light also transmits through the top surface 600 of the asymmetrical blazed grating 402b. However, upon reflection back through the top surface 600, the OOB light is refracted to a direction different than the specular direction. Therefore, asymmetrical blazed gratings 402b appear to deflect both EUV and OOB light away from the substrate 104 and/or the imaging collection pupil.

As shown in FIG. 6C, reflections of incident light upon symmetrical blazed gratings 402a having anti-transmission coatings 602 (ATC) for EUV light (FIG. 6C; left) or OOB light (FIG. 6C; right) are shown. For coated symmetrical blazed gratings 402a receiving EUV light, the EUV beam (e.g., solid-line) is reflected in a different direction from the specular direction, similar to the reflection shown in FIG. 6A. The anti-transmission coating 602 prevents OBB light from penetrating the top surface 600 causing the OOB light to reflect in a direction different than the specular direction. Therefore, the anti-transmission coating 602 causes the symmetrical blazed grating 402a to reflect both EUV and OOB light away from the image collection pupil, similar to the asymmetrical blazed grating 402b.

As shown in FIG. 6D, reflections of incident light upon asymmetrical blazed gratings 402b having anti-transmission coatings 602 (ATC) for EUV light (FIG. 6D; left) or OOB light (FIG. 6D; right) are shown. For anti-transmissive symmetrical blazed gratings 402a, both EUV light and OOB light are deflected toward a direction different from the specular direction, as neither EUV nor OOB light penetrates the top surface 600 of the asymmetrical blazed grating 402b.

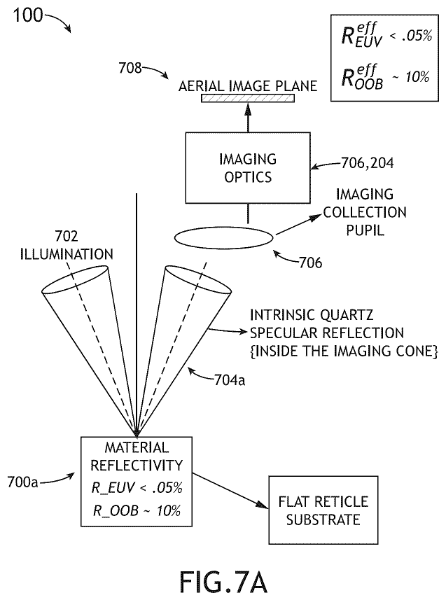

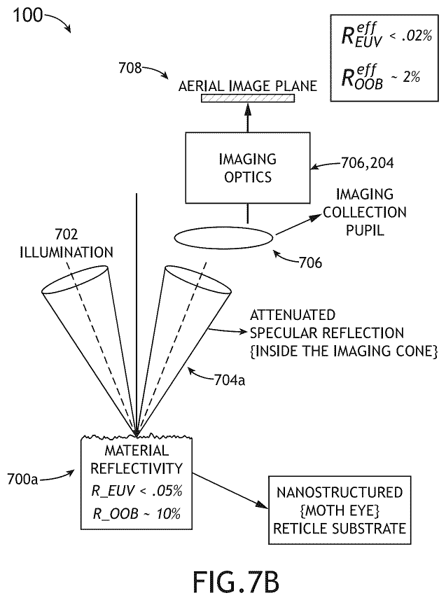

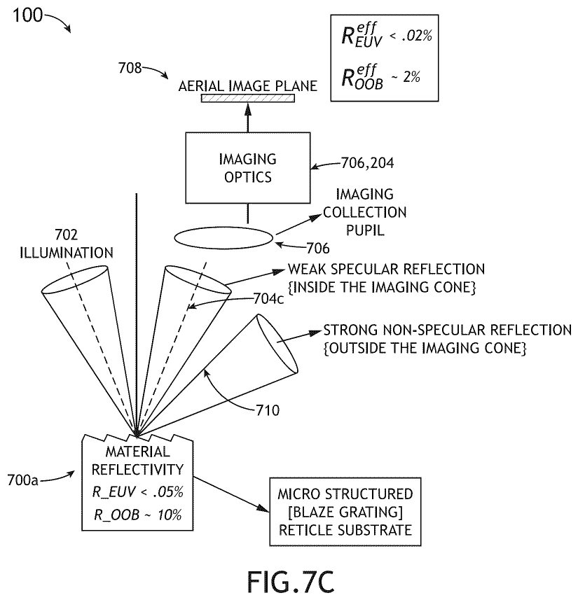

FIGS. 7A-7C illustrate conceptual views of the system 100 illuminating lithography masks 103 configured with different types of black zone surfaces 700a-c (e.g., surfaces for use within dark zones 318) in accordance with one or more embodiments of the disclosure. For example, in dark zones 318 using traditional black bordering (FIG. 7A), the black zone surface 700a is relatively unstructured and flat. Incoming EUV light (e.g., illumination 702) reflects off of the flat black zone surface 700a in a specular reflection (e.g., via intrinsic reflectivity), and the reflected light enters into the imaging cone 704a, where the reflected light may further transmit through the imaging collection pupil, through the imaging optics 706, 204, and onto the aerial image plane 708. The effective reflection R^{eff} of both EUV light and OOB light from the black zone surface 700a is relatively high (R^{eff}_{EUV}<0.05%, R^{eff}_{OOB}˜10%).

Lithography masks 103 using structured, non-grating black bordering, such as the nano-structured moth eye-structured black zone surfaces 700b used in FIG. 7B, light reflected off from the black zone surface 700b is reduced via an anti-reflective property, however, a significant amount of EUV and OOB light is still transmitted through the imaging collection pupil and onto the aerial image plane 708. The effective reflection Reff of both EUV light and OOB light from the structured, not-grating black zone surface 700b remains relatively high (R^{eff}_{EUV}<0.02%, R^{eff}_{OOB}˜2%).

Lithography masks 103 using gratings 402, such as blazed gratings at the black zone surface 700c, deflect light toward an alternate collection cone 710, with only a portion of the light being deflected toward the imaging cone 704c and the aerial image plane 708. The effective reflection Reff of both EUV light and OOB light from the grated black zone surface 700c is lower than the other black zone surface designs (R^{eff}_{EUV}<0.0002%, R^{eff}_{OOB}˜0.3%).

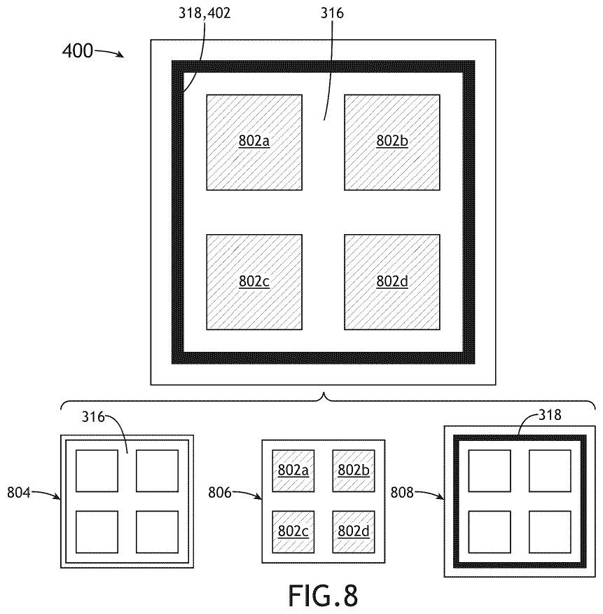

FIG. 8 illustrates a front view of the lithography mask 400, in accordance with one or more embodiments of the disclosure. The lithography mask 400 may include one or more absorber structures 802a-d (e.g., that include multilayer reflective film material, absorber layer material and/or anti-reflective material), etched areas 316 that include reflective film material, but not absorber layer material and/or anti-reflective material, and the dark zones 318 that contains neither the multilayer reflective film material, absorber layer material and/or anti-reflective material). The dark zones 318 may include the blazed gratings 402. In embodiments, the multilayer reflective film 304, the gratings 402 (e.g.,, and/or dark zones 318) and the multilayer reflective film 304 may form a first pattern 804, a second pattern 806 (e.g., a black border pattern), and a third pattern 808, respectively, that combine to form the patterned lithography mask 400. The dark zone 318 provides a black border that prevents incident or emitted illumination from affecting adjacent fields.

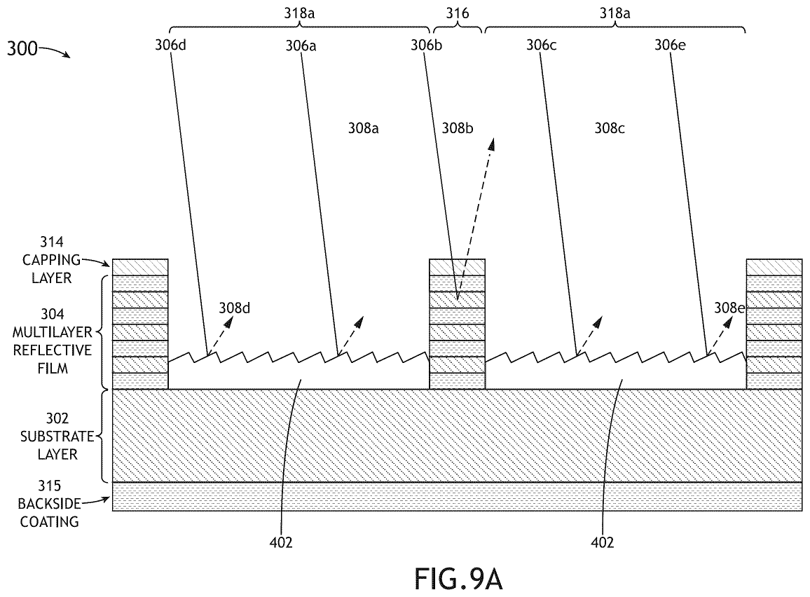

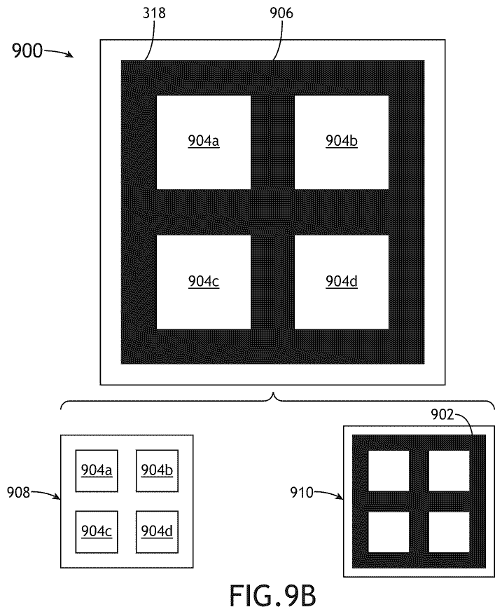

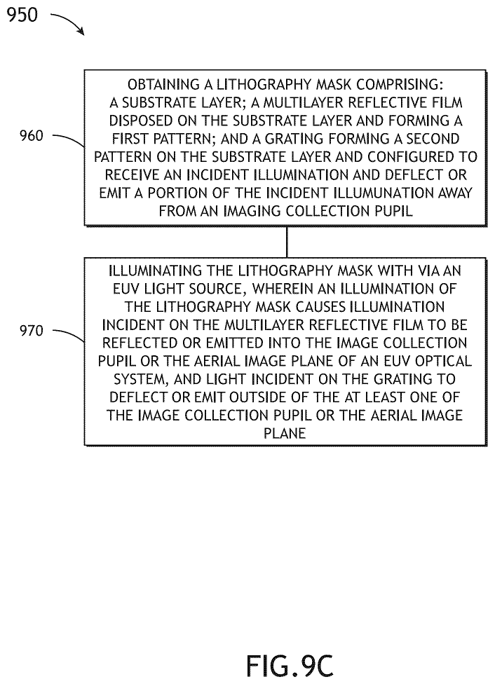

FIG. 9A illustrates a cross-sectional side-view of a lithography mask 900, in accordance with one or more embodiments of the disclosure. The lithography mask 900 may include one or more layers or components as lithography masks 300,400. In embodiments, the lithography mask 900 may include one or more areas comprising a set of field gates 902a-b (e.g., field selection slits), interleaved between regions containing the multilayer reflective film 304 (e.g., analogous to the etched areas 316 areas of lithography mask 300, 400. These field gates 902, also referred to as High Contrast Microscopic Field Gates (HCMFG), may include gratings 402 that spatially modulate illumination distribution in the aerial images and offer an alternate solution for field selection than traditional methods.

By spatially interleaving gratings 402 with areas containing the multilayer reflective film 304 (e.g., in the absence of an absorber layer 310), the patternable spatial illumination modulation by the field gates 902 provides considerable illumination contrast across EUV and OOB light bands. While current patterning on EUV masks involves a combination of multilayer reflective film 304, absorber layer 310 and dark borders without gratings 402 that have poor contrast to OOB, lithography masks 900 that include field gates 902 with gratings 402, such as symmetric or asymmetric blazed gratings, provide considerable contrast spatial illumination modulation for both EUV light and OOB light, as well as e-beam illumination.

The field gates 902 may also provide a substitution for reticle mask blades that are currently used to define areas or fields in the lithography mask 900 where EUV light and/or OOB light will be blocked. The field gates 902 may affect the measurement of EUV system metrics that need to be isolated in the field plane within specific zones, disentangling the impact of the specific zones on the rest of the illuminated area within the field of view (FOV). Field gates 902 are unique because they are part of the lithography mask 900, allowing microscopic spatial control of illumination while providing high contrast between transparent and opaque zones across the entire spectrum from inband (IB) light to OOB light. The field gates 902 utilize the reticle stage for field selection and do not have the added complexity of additional motorized stages and access to a conjugate plane to perform field selection.

FIG. 9B illustrates a front view of the lithography mask 900, in accordance with one or more embodiments of the disclosure. The lithography mask 900 may include one or more multilayer reflective film structures 904a-d (e.g., that do not include absorber layer material and/or anti-reflective material) surrounded by a field gate area 906. The field gate area 906 may include or be positioned adjacent to a black border (e.g., dark zone 318). The lithography mask 900 may include a first pattern 908 of multilayer reflective film structures 904a-d, and a second pattern 910 comprised of field gates 902 (e.g., containing one or more gratings 402). In embodiments, the lithography mask 400, 900 may include sets of blazed gratings 402 and/or blazed grating patterns organized around, or otherwise blended with, nano-scale EUV patterns containing one or more multilayer reflective film structures 904a-d and/or one or more absorber structures 802a-d.

In embodiments, the second pattern 910 may include gratings of reflective film (e.g., structures 452a, 452b) that are deposited on the gratings 402a, 402b, as shown in FIG. 4B. For example, the second pattern 910 may include multilayer reflective film 304 that is deposited on top of the substate layer 302 (e.g., and gratings 402a, 402b) such that the multilayer reflective film 304 follows the pattern of the gratings 402. In embodiments, the first pattern 908 and the second pattern 910 together include a contiguous layer of multilayer reflective film 304. For example, having both the first pattern 908 and the second pattern 910 layered with a contiguous layer of multilayer reflective film 304 may cause the first pattern 908 and the second pattern 910 to have electrical continuity, allowing the lithography mask 900 to be inspected via e-beam methods.

In embodiments, the field gate areas 906 assist in field selection processes. For example, in applications for which field selection on the reticle/mask plane becomes critical and for which access to a large field conjugate plane for field selection using physical actuated slits, such as reticle masking blades is challenging, micro engineering field slits such as gratings 402 directly on the reticle/lithography mask 103 is an elegant solution precluding the need for reticle masking blades. These applications may include, but are not limited to, the design of targets for optical flare, and measurement of field-limited far-field patterns. Both of the aforementioned applications require exceptional illumination suppression outside a region of interest similar to what a slit element or grating 402. For example, field gates 902 can be used for determining optical flare measurements and field-dependent pupil parameters, such as where a long-range fingerprint of an open multilayer (ML) area (e.g., due to the band flare kernel) needs to be determined. The use of gratings 402 in dark zones 318 and field gates 902 may further replace or lessen the need for spectral purity filters often required in EUV systems.

For realizing such a slit element or grating 402 in reflective geometry, the reflected or emitted illumination (e.g. EUV light, OOB light, and/or electron beam) from outside the transmitted illumination area of a slit (e.g., the opaque part of the slit) either needs to be substantially attenuated or deflected elsewhere to achieve effective opacity as seen by the optical elements downstream. The illumination attenuation outside the slit opening or grating 402 is not effective if the dark zone is engineered as a traditional EUV absorber layer 310, due to the non-negligible residual illumination leakage (˜1.4%) in the EUV and high average reflectivity (˜50%) at the OOB bands.

While an NBB surrounding a multilayer reflective film structure 904, in principle, is a strong candidate for EUV field selection, the ˜10% OOB reflectivity (5% from front surface and 5% from back reflection) from the NBB areas essentially renders them ineffective as a generalized solution for field gating across a broad band. Here, we extend the grating principle proposed for DBB in scanners and other lithography sub-systems 102 to low/medium NA EUV imaging systems (NA<0.4) to devise miniaturized micron-sized slits (e.g., gratings 402) for both EUV and OOB field selection. The illumination transmission zone in this device is a multilayer reflective film structure 904 and the opaque (in reflective mode) area surrounding is engineered as either (1) an asymmetric blazed grating on the glass substrate or (2) a symmetric/asymmetric blazed grating with anti-transmission coating. By relying on the principle of deflection instead of illumination attenuation, the gratings 402 show contrast as high as >200× in the EUV and >30× in OOB translating to low effective reflectivity values of 0.00025% in EUV and 0.3% in OOB, covering a broad band of wavelengths from EUV to IR.

FIG. 9C illustrates a process flow diagram depicting a method 950 for attenuating a reflection of at least one of unintended extreme ultraviolet (EUV) light or out-of-band (OOB) light out of an image collection pupil or an aerial image plane of a EUV lithography system 100 or EUV inspection system 150 (e.g., optical systems), in accordance with one or more embodiments of the disclosure. For example, the method 950 may be configured to attend reflection from zones (e.g., such as pre-engineered zones) of the optical systems.

In embodiments, the method 950 includes a step 960 of obtaining a lithography mask 103 comprising a substrate layer 302, a multilayer reflective film 304 disposed on the substrate layer and forming a first pattern; and a grating 402 forming a second pattern on the substrate layer and configured to receive an incident light and deflect or emit a portion of the incident light outside an imaging collection pupil. For example, the step 960 may include one or more lithography masks 400, 900 disclosed herein.

In embodiments, the method 950 includes a step 970 of illuminating the lithography mask 103, 400, 900 via the EUV light source 202, wherein an illumination of the lithography mask 103, 400, 900 causes a light incident on the multilayer reflective film 304 to be reflected into the image collection pupil or the aerial image plane 708 of the EUV lithography system 100 or the EUV inspection system 150, and causes light incident on the grating 402 to deflect or emit outside of the at least one of the image collection pupil or the aerial image plane 708. The grating 402 may be incorporated into a dark zone 318 or dark zone pattern within the lithography mask 103, 400, 900 as part of a black border/DBB or as a set of field gates 902. In embodiments, the second pattern 910 includes multilayer reflective film disposed on the grating that is contiguous with the multilayer reflective film 304 of the first pattern 908, wherein the first pattern 908 and the second pattern 910 have electrical continuity.

The following examples describe and demonstrate exemplary embodiments of systems and methods described herein. The examples are provided solely for the purpose of illustration and are not to be construed as limitations of the present disclosure, as many variations thereof are possible without departing from the spirit and scope of the present disclosure.

### Example I: Far-Field Intensity Distribution From a Blazed Grating in NA Space

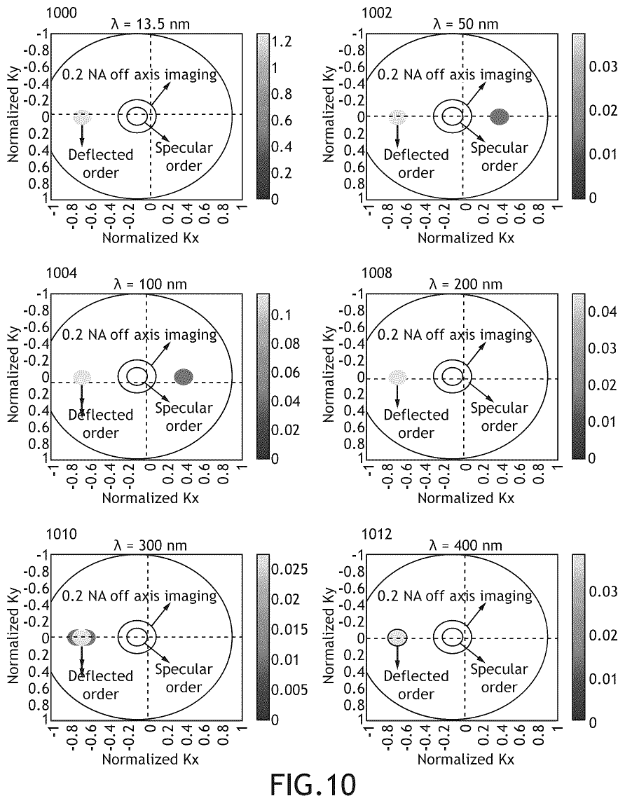

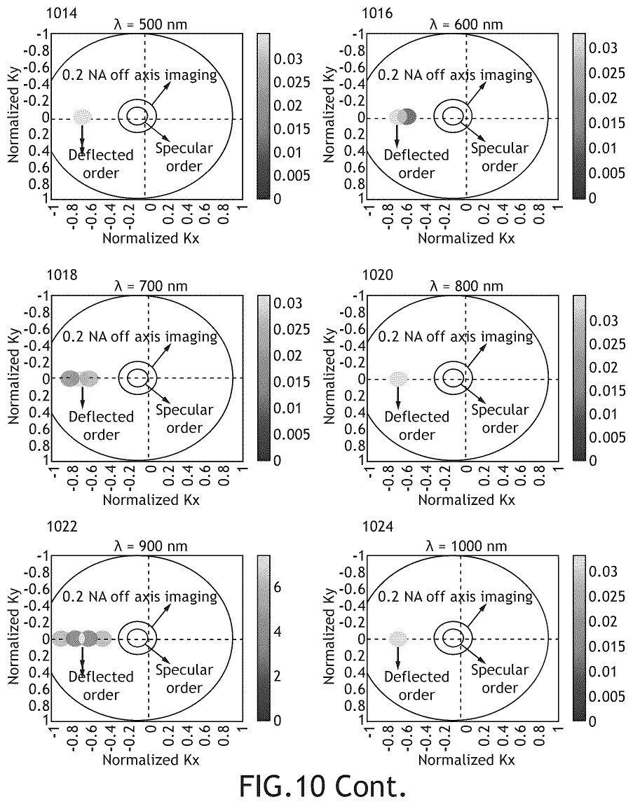

FIG. 10 illustrates an array of graphs 1000-1024 depicting simulations of far-field diffraction patterns from a blazed grating at different wavelengths in a finite difference time domain (FDTD), according to one or more embodiments of the disclosure. Each graph 1000-1024 discloses the ability of the grating 402 to deflect a beam (e.g., a deflected order) as compared to specular reflection (e.g., a specular order) relative to the collection imaging NA of the system 100.

As shown in FIG. 10, across the wavelength range 13.5 nm-1000 nm, the strongest diffracted order is not the specular, but rather the deflected beam due to the blaze angle of the blazed grating 402. In each graph 1000-1024, the deflected beam is pushed out of the collection imaging NA of the system, suggesting considerable light level suppression in the aerial image. These simulations were generated utilizing virtual uncoated asymmetric blaze gratings 402 with a depth of 2 um and a blaze pitch of 7 um. For certain wavelengths (e.g., lambda=900 nm in graph 1022), the deflected beam energy is distributed across different orders due to the lack of a matching order at the blaze-determined angle. The order spacing is determined by the pitch and wavelength, while the deflection angle is determined by the blaze angle. The beam momentum is conserved by distributing it across the available orders.

### Example II: Enhancement of Attenuation of Reflected Light in DBB Over NBB

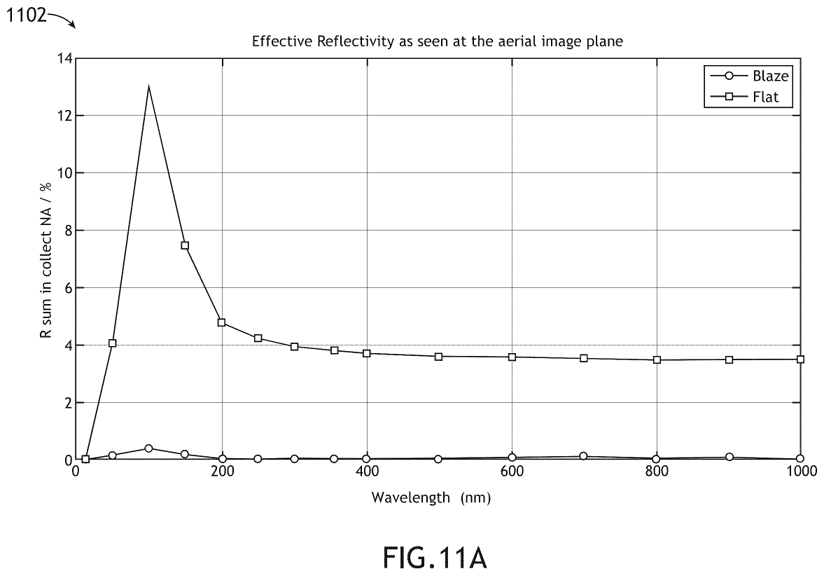

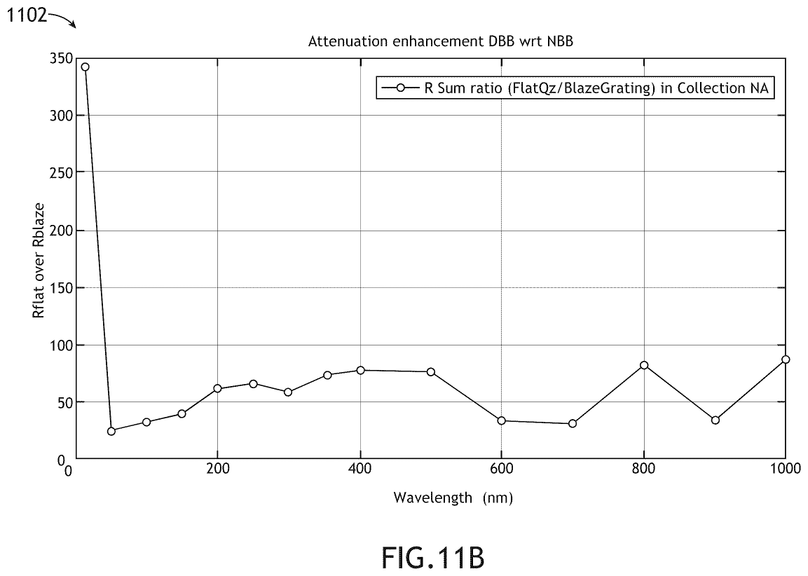

FIG. 11A illustrates a graph 1100 depicting simulations of effective reflectivity of the light for DBB (e.g., “Blaze”) and NBB (e.g., “Flat”) as seen at the aerial image plane of the system 100, in accordance with one or more embodiments of the disclosure. Effective reflectivity is measured as the percentage of light that is collected in the NA. A graph 1102 illustrating the ratio of values between DBB and NBB effective reflectivity is shown in FIG. 11B. As shown in FIGS. 11A-11B, for EUV in-band light (e.g., wavelengths less than 200 nm) the DBB attenuation is as much as 350× with respect to NBB. For the OOB band (e.g., wavelengths greater than 200 nm), the DBB attenuation is as much as 50× with respect to NBB. The lower performance for DBB in reducing OOB reflection into the aerial image plane may be attributed to increased diffraction effects at OOB wavelengths. For deflecting light out of the imaging system (e.g., aerial image plane) it may be necessary that the “strong” order due to the blaze grating 402 matches a diffraction order, the diffraction order pre-determined by the wavelength and pitch.

### Example III: Reflectivity Comparisons Between DBB and NBB

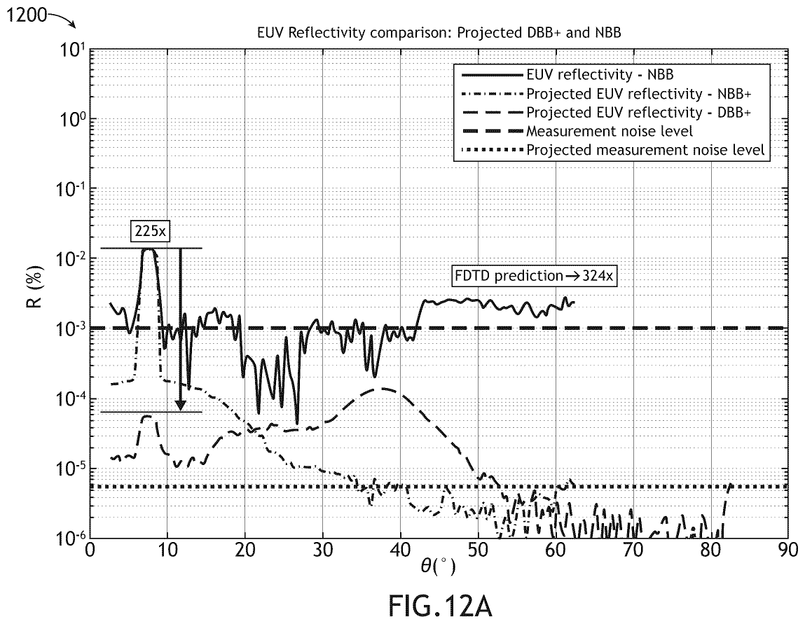

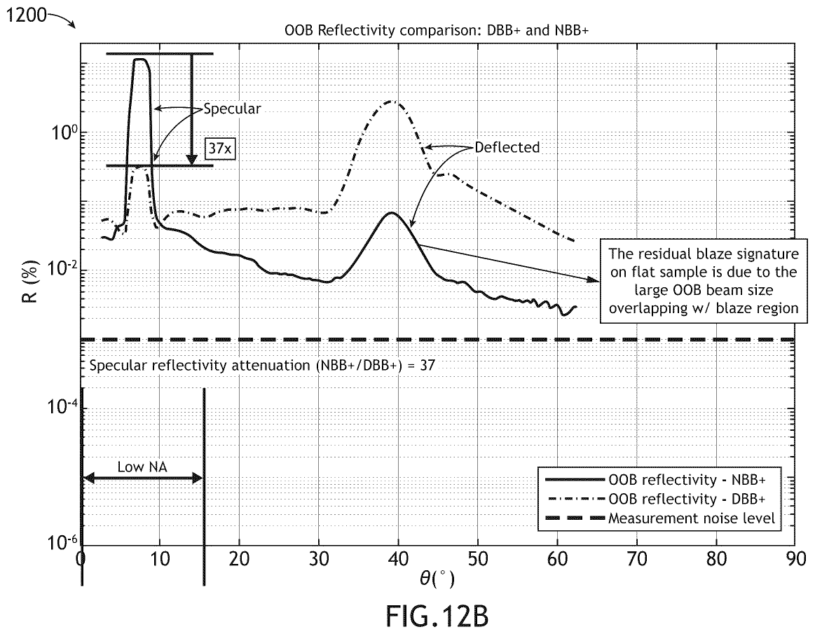

FIGS. 12A-12B illustrate graphs 1200, 1202 depicting reflectivity comparisons between DBB and NBB for EUV light and OOB light, respectively, in accordance with one or more embodiments of the disclosure.

Referring to FIG. 12A, reflectometer measurements showing the suppression of specular content and the appearance of light at the deflected direction showing the suppression of specular EUV within the collection cone and the expulsion of EUV light outside the low NA collection cone. The blue curve represents the flat Quartz sample (e.g., NBB) and the red represents the blazed quartz sample (e.g., DBB).

Referring to FIG. 12B, reflectometer measurements showing the suppression of specular content and the appearance of light at the deflected direction showing the suppression of specular OOB within the collection cone and the expulsion of OOB light outside the low NA collection cone. The blue curve represents the flat Quartz sample (e.g., NBB) and the red represents the asymmetric blazed quartz sample (e.g., DBB).

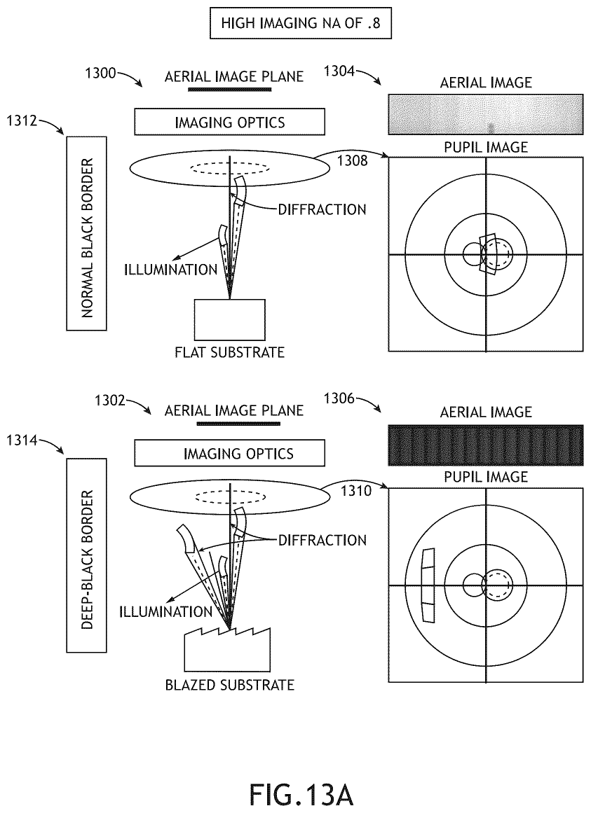

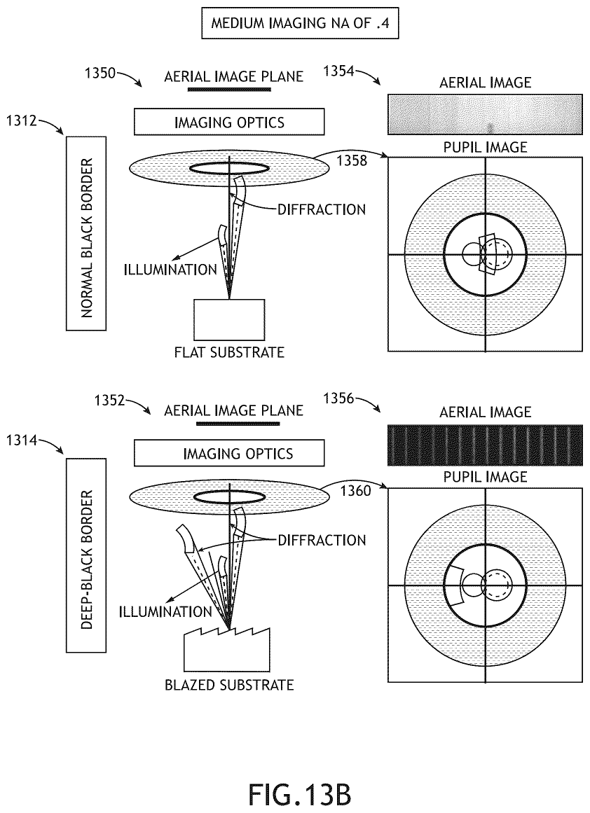

FIG. 13A illustrates simulated reflection states 1300, 1302 and respective aerial images 1304, 1306 and pupil images 1308, 1310 for tested normal black border substrates 1312 (e.g., flat quartz target) and deep-black border substrates 1314 (e.g., blazed quartz target with a depth of 2 um and pitch of 7 um) at 198 nm with an imaging NA of 0.8, in accordance with one or more embodiments of the disclosure. The pupil images 1308,1310 illustrate the diffraction from the respective targets and the aerial images 1304, 1306 display the image plane light level.

FIG. 13B illustrates simulated reflection states 1350, 1352 and respective aerial images 1354, 1356 and pupil images 1358, 1360 for tested normal black border substrates 1312 (e.g., flat quartz target) and deep-black border substrates 1314 (e.g., blazed quartz target with a depth of 2 um and pitch of 7 um) at 198 nM with an imaging NA of 0.4, in accordance with one or more embodiments of the disclosure. The pupil images 1358,1360 illustrate the diffraction from the respective targets and the aerial images 1354, 1356 display the image plane light level.

Referring to FIGS. 13A and 13B, switching from high NA (0.8 NA) to medium NA (0.4 NA) imaging mode when scanning normal black border substrates 1312 has little impact on the aerial image light level. However, due to the strongest order being outside the low NA collection cone, the normal black border substrates 1312 show a marked difference in light levels as the imaging collection cone is switched from high NA to medium NA. These results illustrate the efficacy of blazed grating 402 in light suppression in low to medium NA mode, creating dark zones 318 such as deep-black borders.

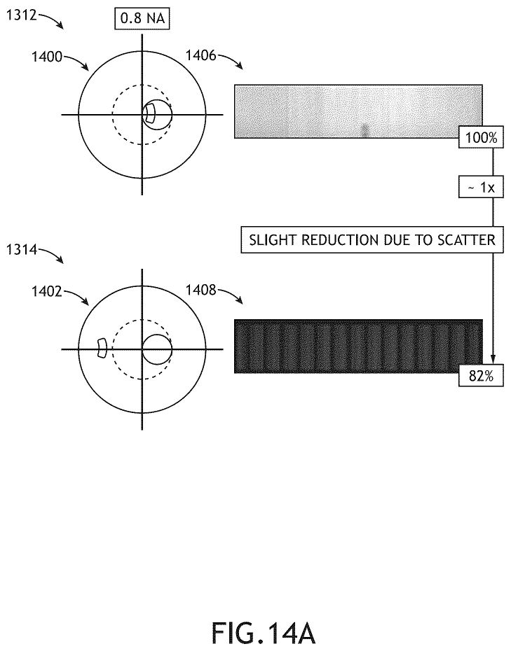

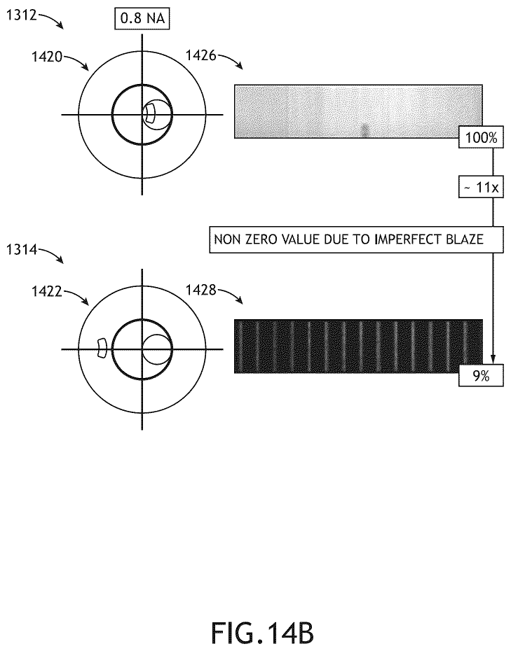

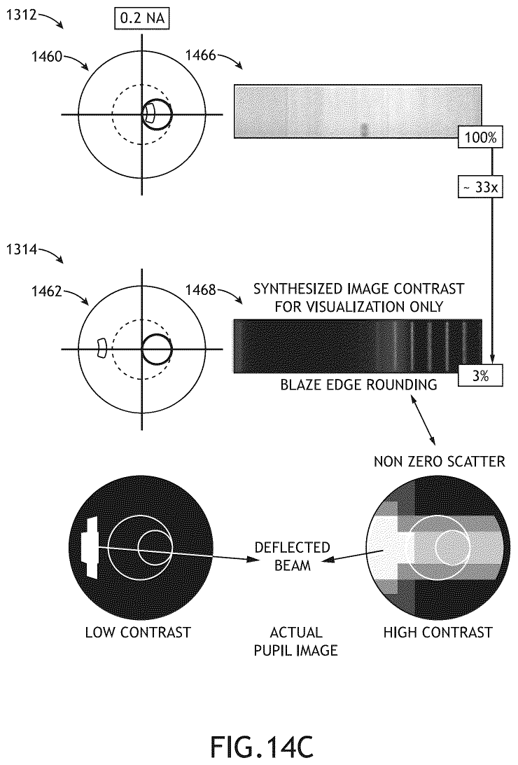

FIG. 14A illustrates simulated pupil images 1400, 1402 and aerial images 1406, 1408 of light reflecting from a respective normal black border substrate 1312 and a deep-black border substrate 1314 at 198 nM with an imaging NA of 0.8 (e.g., high NA), in accordance with one or more embodiments of the disclosure. FIG. 14B illustrates simulated pupil images 1420, 1422 and aerial images 1426, 1428 of light reflecting from a respective normal black border substrate 1312 and a deep-black border substrate 1314 at 198 nM with an imaging NA of 0.4 (e.g., medium NA) in accordance with one or more embodiments of the disclosure. FIG. 14C illustrates simulated pupil images 1460, 1462 and extrapolated aerial images 1466, 1468 of light reflecting from a respective normal black border substrate 1312 and a deep-black border substrate 1314 at 198 nM with an imaging NA of 0.2 (e.g., low NA) in accordance with one or more embodiments of the disclosure. FIG. 14C further includes an actual low-contrast pupil image 1470 and an actual high-contrast pupil image 1472.

Referring to FIGS. 14A-14C, while the difference in light suppression between NBB and DBB is increased 11-fold when switching from high NA to medium NA, extrapolating the light suppression from medium NA to low NA, decreases the amount of light in the aerial image further by an additional factor of 3, resulting in an overall reduction of 33× the average OOB light levels on the aerial image for DBB with respect to NBB. Medium (0.4) and low (0.2) NA imaging systems, akin to current EUV imaging systems, are therefore positively affected by the use of gratings 402 where the deflected light from the lithography mask 20,400, 900 or reticle can be pushed away from the imaging collection cone.

While asymmetric gratings provide a high degree of suppression for both EUV light levels and OOB light levels at the aerial image plane, a symmetric grating is less effective for reflected OOB light. For the case of symmetric gratings, back-reflected OOB light from the macroscopic grating structure can re-enter the imaging path (e.g., similar to specular reflection), making them less effective targets for OOB light attenuation. Asymmetric gratings on the other hand do not have this limitation owing to the broken symmetry prevalent at the interface at re-entry vs entry, preventing specular-like reflection of the back reflected OOB light. In lithography mask designs that involve specialized coating on the blazed structures that prevent transmission of OOB light into the substrate 104, a high degree of suppression of light levels can be achieved for both the symmetric and asymmetric designs across the EUV and OOB part of the spectrum. The anti-transmission coatings in these variants may prevent the transmission of OOB light into the substrate 104 and thereby avoiding back reflection.

Normal Black Borders (NBB) and Hybrid Black Borders (HBB) are ubiquitous on current generation EUV lithography photomasks 103, producing dark zones 318 at the border of the pattern field on an EUV reticle from which both EUV and OOB light is substantially attenuated relative to the patterned areas. In a lithography sub-system 102, the wafer projections of these dark zones 318 enable tight critical dimension (CD) control at the edges of the imaging fields which experience higher dose levels from multiple exposures compared to the core. For this reason, the requirement of both EUV and OOB attenuation from black borders are extremely high at <0.05% and <10%, respectively. Deep-black borders (DBB), utilizing gratings 402 as disclosed herein, reduce by more than an order of magnitude (>200× in EUV and 30× on OOB in NBB) light levels at the aerial image plane, both in the EUV and OOB bands, with effective reflectivity of <0.00025% and <0.3% respectively. DBB surpasses the attenuation offered by previous inventions, which primarily rely on specular light suppression either by choice of the material or engineering its surface for anti-reflection by graded refractive indexing. Instead of targeting low light levels exiting right at the reticle, DBB demonstrates light suppression differently by combining light deflection offered by the blazed grating 402 and its expulsion from the system collection cone. Note that in this scheme, unlike traditional light attenuation, the light level exiting the reticle can be high, but the average momentum of that light is away from the imaging path, paving way for dark aerial images and consequently deep-black borders.

As described herein, the black bordering implementation in NBB is based on attenuating the reflected light, and HBB implementation is based on anti-reflection. In contrast, the primary principle in DBB is light deflection and not attenuation or anti-reflection. DBB relies on (a) microscopic tilted facets on the target surface (e.g., gratings 402) to expel light from the specular and (b) the low-medium NA of the EUV systems that allow the light expulsion. Light attenuation for NBB is achieved by the simple choice of glass substrate as the material target. For instance, it is known that the glass substrates reflect only 0.05% EUV and 5-10% OOB, depending on the wavelength. HBB realization is a little more nuanced and involves the use of nanostructures. Nanostructuring of the same glass substrate to create moth eye patterns can reduce the OOB reflectivity from 10% to ˜1-2%. This is achieved by creating a refractive index gradient in the z direction that suppresses reflection. However, deflection in DBB is achieved by blazed gratings 402 on the substrate layer 302. The blazed grating 402 that we have considered for deflecting the beam away from the specular path typically has a pitch>4 um and a depth between 500 nm and 3 um. Though for demonstration we consider only 1D gratings, in principle the blazed sample can be 2D blazed gratings as well.

The one or more processors 108, 174 of the controller 106, 172 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 108, 174 may include any device configured to execute algorithms and/or instructions (e.g., program instructions stored in memory). In embodiments, the one or more processors 108, 174 may be embodied as a desktop computer, mainframe computer system, workstation, image computer, parallel processor, networked computer, or any other computer system configured to execute a program configured to operate or operate in conjunction with the lithography system 100 or inspection system 150, as described throughout the present disclosure

The memory medium 110, 176 may include any storage medium known in the art suitable for storing program instructions executable by the associated one or more processors 108, 174. For example, the memory medium 110, 176 may include a non-transitory memory medium. By way of another example, the memory medium 110, 176 may include, but is not limited to, a read-only memory (ROM), a random-access memory (RAM), a magnetic or optical memory device (e.g., disk), a magnetic tape, a solid-state drive and the like. It is further noted that memory medium 110, 176 may be housed in a common controller housing with the one or more processors 108, 174. In embodiments, the memory medium 110, 176 may be located remotely with respect to the physical location of the one or more processors 108, 174 and controller 106, 172. For instance, the one or more processors 108, 174 of controller 106, 172 may access a remote memory (e.g., server), accessible through a network (e.g., internet, intranet and the like).

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable and/or wirelessly interacting components, and/or logically interacting and/or logically interactable components.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed:

1. A lithography mask comprising:
a substrate layer;
a multilayer reflective film disposed on the substrate layer and forming a first pattern, wherein the multilayer reflective film is configured to receive incident illumination and reflect or emit a portion of the incident illumination toward an imaging collection pupil; and
a grating forming a second pattern on the substrate layer and configured to receive the incident illumination and deflect an additional portion of the incident illumination outside of the imaging collection pupil.

2. The lithography mask of claim 1, wherein the grating comprises a blazed grating.

3. The lithography mask of claim 1, wherein the second pattern comprises a black border pattern.

4. The lithography mask of claim 1, further comprising an absorber layer disposed on the multilayer reflective film or a capping layer and forming a third pattern.

5. The lithography mask of claim 1, wherein the second pattern comprises a multilayer reflective film deposited on top of the grating wherein the multilayer reflective film deposited on top of the grating follows the pattern on the grating.

6. The lithography mask of claim 5, wherein the multilayer reflective film of the second pattern forms a at least one of symmetric or asymmetric grating.

7. The lithography mask of claim 6, wherein the multilayer reflective film of the first pattern and the multilayer reflective film of the second pattern have electrical continuity.

8. The lithography mask of claim 1, wherein the second pattern comprises a set of field gates.

9. The lithography mask of claim 8, wherein a reflection of EUV light or OOB light from the set of field gates is used to measure optical flare and field dependent pupil parameters.

10. The lithography mask of claim 2, wherein the blazed grating comprises a symmetric blazed grating element.

11. The lithography mask of claim 10, further comprising an anti-reflective coating disposed on the symmetric blazed grating element.

12. The lithography mask of claim 2, wherein the blazed grating comprises asymmetric blazed grating elements.

13. The lithography mask of claim 12, further comprising an anti-reflective coating disposed on the asymmetric blazed grating elements.

14. The lithography mask of claim 1, wherein the incident illumination comprises extreme ultraviolet light and out of band light.

15. The lithography mask of claim 1, further comprising a capping layer disposed on the multilayer reflective film.

16. A lithography system comprising:
a lithography sub-system comprising a set of optical elements; and
a lithography mask comprising:
a substrate layer;
a multilayer reflective film disposed on the substrate layer and forming a first pattern, wherein the multilayer reflective film is configured to receive incident illumination and reflect or emit a portion of the incident illumination toward an imaging collection pupil; and
a grating forming a second pattern on the substrate layer and configured to receive the incident illumination and deflect or emit an additional portion of the incident illumination outside of the imaging collection pupil.

17. The lithography system of claim 16, wherein the grating comprises a blazed grating.

18. The lithography system of claim 16, wherein the second pattern comprises a black border pattern.

19. The lithography system of claim 16, further comprising an absorber layer disposed on the multilayer reflective film or a capping layer and forming a third pattern.

20. The lithography system of claim 16, wherein the second pattern comprises a set of field gates.

21. The lithography system of claim 17, wherein the blazed grating comprises a symmetric blazed grating element.

22. The lithography system of claim 21, further comprising an anti-reflective coating disposed on the symmetric blazed grating elements.

23. The lithography system of claim 17, wherein the blazed grating comprises asymmetric blazed grating element.

24. The lithography system of claim 23, further comprising an anti-reflective coating disposed on the asymmetric blazed grating elements.

25. The lithography system of claim 16, wherein the incident illumination comprises extreme ultraviolet light.

26. The lithography system of claim 16, wherein the lithography mask further comprises a capping layer disposed on the multilayer reflective film.

27. An inspection system comprising:
an illumination source configured to generate a beam of illumination;
a stage configured to secure an extreme ultraviolet (EUV) lithography mask, wherein the EUV lithography mask comprises:
a substrate layer;
a multilayer reflective film disposed on the substrate layer and forming a first pattern, wherein the multilayer reflective film is configured to receive incident illumination and reflect or emit a portion of the incident illumination toward an imaging collection pupil; and
a grating forming a second pattern on the substrate layer and configured to receive the incident illumination and deflect or emit an additional portion of the incident illumination outside of the imaging collection pupil;
a set of optical elements; and
a detector, wherein the set of optical elements is configured to direct illumination to the EUV lithography mask and direct illumination from the EUV lithography mask to the detector.

28. The inspection system of claim 27, wherein the illumination source comprises at least one of an EUV light source configured to generate an extreme ultraviolet (EUV) light illumination beam or an electron beam source configured to generate an electron beam.

29. The inspection system of claim 27, wherein the inspection system comprises at least one of an actinic patterned mask inspection system or an electron beam (e-beam) inspection system.

30. The inspection system of claim 27, wherein the grating comprises a blazed grating.

31. The inspection system of claim 27, wherein the second pattern comprises a black border pattern.

32. The inspection system of claim 27, further comprising an absorber layer disposed on the multilayer reflective film or a capping layer and forming a third pattern.

33. The inspection system of claim 27, wherein the second pattern comprises a set of field gates.

34. The inspection system of claim 30, wherein the blazed grating comprises symmetric blazed grating elements.

35. The inspection system of claim 34, further comprising an anti-reflective coating disposed on the symmetric blazed grating elements.

36. The inspection system of claim 30, wherein the blazed grating comprises asymmetric blazed grating elements.

37. The inspection system of claim 36, further comprising an anti-reflective coating disposed on the asymmetric blazed grating elements.

38. The inspection system of claim 28, wherein the EUV lithography mask further comprises a capping layer disposed on the multilayer reflective film.

39. A method for attenuating a reflection from pre-engineered zones of an extreme ultraviolet light (EUV) mask comprising:
obtaining a lithography mask comprising:
a substrate layer;
a multilayer reflective film disposed on the substrate layer and forming a first pattern; and
a grating forming a second pattern on the substrate layer and configured to receive an incident illumination and deflect or emit a portion of the incident illumination outside an imaging collection pupil; and
illuminating the lithography mask with via an illumination source wherein an illumination of the lithography mask causes illumination incident on the multilayer reflective film to be reflected or emitted into an image collection pupil or an aerial image plane of an optical system, wherein the lithography mask causes illumination incident on the grating to deflect or emit outside of the at least one of the image collection pupil or the aerial image plane.

40. The method of claim 39, wherein the illumination source comprises an EUV illumination source.

41. The method of claim 39, wherein the illumination source comprises an electron beam source.

42. The method of claim 39, wherein the grating comprises a blazed grating of the substrate layer.

43. The method of claim 39, wherein the lithography mask further comprises multilayer reflective film deposited on the grating of the second pattern, wherein the multilayer reflective film of the first pattern and the second pattern are contiguous.

44. The method of claim 39, wherein the second pattern comprises a black border pattern.

45. The method of claim 39, wherein the second pattern comprises a set of field gates.

46. The method of claim 42, wherein the blazed grating comprises a symmetric blazed grating element.

47. The method of claim 46, further comprising an anti-reflective coating disposed on the symmetric blazed grating elements.

48. The method of claim 42, wherein the blazed grating comprises asymmetric blazed grating elements.

49. The method of claim 48, further comprising an anti-reflective coating disposed on the asymmetric blazed grating element.

50. The method of claim 39, wherein the grating causes an attenuation of a reflection of unintended EUV light into the image collection pupil or the aerial image plane of the optical system.

51. The method of claim 39, wherein the grating causes an attenuation of a reflection of out-of-band (OOB) light into the image collection pupil or the aerial image plane of the optical system.

52. The method of claim 39, wherein the second pattern includes multilayer reflective film disposed on the grating that is contiguous with the multilayer reflective film of the first pattern, wherein the first pattern and the second pattern have electrical continuity.
